(19) United States
(12) Patent Application Publication
(10) Pub. No.: US 2009/0166889 A1
(43) Pub. Date: Jul. 2, 2009

(54) PACKAGED INTEGRATED CIRCUITS HAVING SURFACE MOUNT DEVICES AND METHODS TO FORM PACKAGED INTEGRATED CIRCUITS

(76) Inventors: Rajen Murugan, Garland, TX (US); Peter R. Harper, Lucas, TX (US); Mark Gerber, Lucas, TX (US)

Correspondence Address: TEXAS INSTRUMENTS INCORPORATED, P O BOX 655474, M/S 3999, DALLAS, TX, 75265, US

(21) Appl. No.: 11/967,844

(22) Filed: Dec. 31, 2007

(51) Int. Cl. H01L 23/48; H01L 21/00

(52) U.S. Cl. 257/777; 438/127; 257/E23.01; 257/E21.001

(57) ABSTRACT

Packaged integrated circuits having surface mount devices and methods to form the same are disclosed. A disclosed method comprises attaching an integrated circuit to a first side of a substrate, forming one or more first conductive elements on the substrate, attaching a surface mount device to a second side of the substrate via the first conductive elements, forming one or more second conductive elements on the second side of the substrate.

### FIELD OF THE DISCLOSURE

The present disclosure generally relates to integrated circuits and, more particularly, to packaged integrated circuits having surface mount devices and methods to form the same.

### BACKGROUND

Generally, integrated circuits are placed in a small package and routes signals to and from the integrated circuit. In some examples, the packaged integrated circuits are attached to a circuit board of a portable electronic device, which typically has limited circuit board space. To meet consumer desire for smaller portable electronic devices, semiconductor manufacturers seek to make transistors and integrated circuits smaller, thereby reducing the final size of the integrated circuits and their corresponding packages.

In addition, transistors and/or integrated circuits have been made to run faster to handle high frequency signals for applications such as, for example, wireless communications, gaming, digital signal processing, and so forth. At the same time, consumers desire portable electronic devices that integrate more functions, thereby requiring additional circuitry to accommodate these functions. As a result, electronic devices are becoming more smaller and more densely packed with circuitry. In such circumstances, the close proximity of the circuitry (e.g., transistors, bond wires, etc.) to each other cause increased interference (e.g., electromagnetic interference, etc.) and other parasitic effects (e.g., effective series resistances, etc.). For example, switching noise from a power distribution network may cause electromagnetic interference that may disturb other signals of the integrated circuits.

Generally, to reduce interference and other parasitic effects, low impedance paths to ground are implemented to remove high frequency noise. Because the package has limited space, such low impedance paths to ground are typically implemented on the circuit board, thereby consuming valuable circuit board space.

### SUMMARY

Packaged integrated circuits having passive devices and methods to form the same are disclosed. An example method to form such an integrated circuit includes attaching an integrated circuit to a first side of a substrate and forming one or more first conductive elements on the substrate. A surface mount device is then attached to a second side of the substrate via the first conductive elements. One or more second conductive elements are then formed on the second side of the substrate. In some examples, the first and second conductive materials are implemented via different materials, for example, a conductive epoxy and a solder, respectively. However, in other examples, a fastening element may be applied to encapsulate the surface mount device to secure it during later processes.

### BRIEF DESCRIPTION OF THE DRAWINGS

FIG. 1 illustrates an example packaged integrated circuit having an example surface mount device.

FIG. 2 illustrates the example packaged integrated circuit of FIG. 1 attached to a circuit board.

FIG. 3 illustrates a portion of the example packaged integrated circuit of FIG. 2 attached to a circuit board in more detail.

FIG. 4 is a flow diagram of an example process that may be used to make the example packaged integrated circuit of FIG. 1.

FIGS. 5A-5I are illustrations of an example packaged integrated circuit at different stages of the example process of FIG. 4.

FIG. 6 illustrates another example packaged integrated circuit implementing a surface mount device.

FIG. 7 illustrates another example packaged integrated circuit implementing a surface mount device.

FIG. 8 illustrates yet another example packaged integrated circuit implementing a surface mount device.

FIG. 9 illustrates yet another example packaged integrated circuit implementing a surface mount device.

To clarify multiple layers and regions, the thicknesses of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Packaged integrated circuits with surface mount devices and methods to form the same are disclosed herein. Although the example methods and apparatus described herein generally relate to diminishing noise to improve performance, the disclosure is not limited to reducing noise. On the contrary, the teachings of this disclosure may be applied to any integrated circuit which would benefit from placing any device on a surface of a packaged integrated circuit for any suitable purpose.

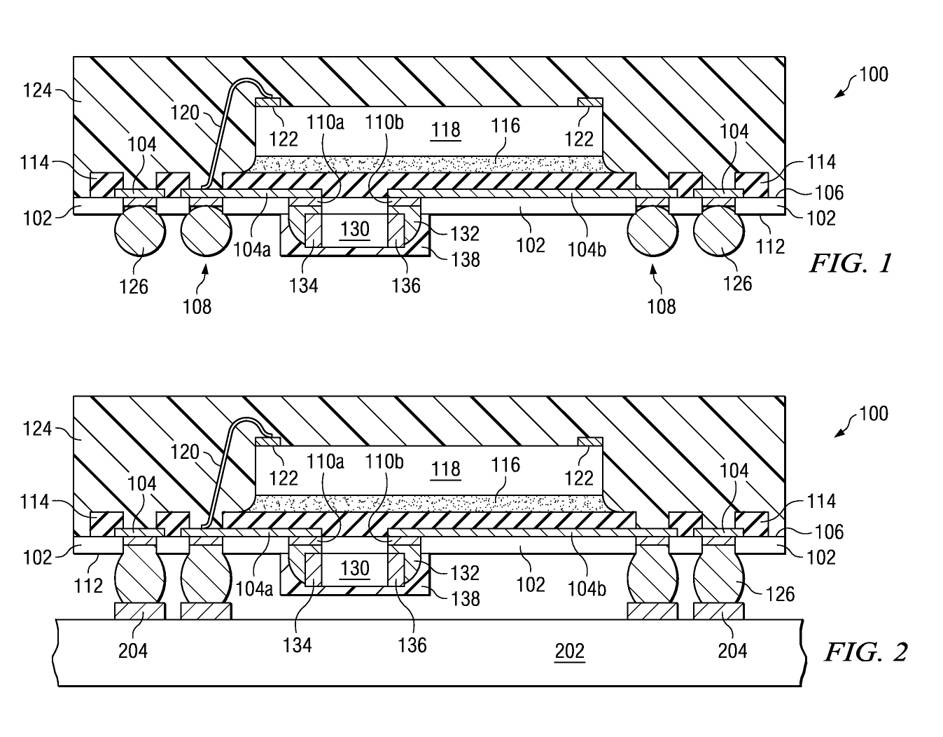

FIG. 1 is a cross sectional view of an example packaged integrated circuit 100 having surface mount devices attached thereto. The example integrated circuit 100 includes a substrate 102 having one or more conductive pads 104 (e.g., copper, etc.) disposed on a first surface 106. In some examples, the substrate 102 is implemented by a dielectric material (e.g., a polyimide, etc.) defining one or more holes 108. To form the pads 104, a metal layer (e.g., a metal tape, plating, etc.) is attached to the first surface 106. The metal layer is then selectively removed by any suitable process (e.g., etching, etc.), thereby forming the pads 104. In some examples, one or more electrically conductive plugs 110 may be placed into the holes 108. As shown in FIG. 1, the plugs 110 may be flush with the first surface 106 of the substrate 102, but do not extend to a second surface 112 of the substrate 102. Thus, the plugs 110 are in contact with the pads 104 of the substrate 102. A protective layer 114 (e.g., a laminate) covers portion(s) of first surface 106 of the substrate 102 while leaving portions of the pads 104 exposed.

In the example of FIG. 1, an adhesive 116 (e.g., an epoxy, etc.) is selectively applied to the protective layer 114 and an integrated circuit 118 is attached to the protective layer 114 and, thus, to the substrate 102 via the adhesive 116. In other examples, the integrated circuit 118 may be attached to any other part of the substrate 102 via any suitable process (e.g., a flip-chip process, a eutectic die attach, etc.). To electrically couple the integrated circuit 118 with the pads 104, one or more bond wires 120 are placed between one or more contacts 122 of the integrated circuit 118 and their respective pads 104. The bond wires 120 may be implemented by any suitable material (e.g., gold, aluminum, etc) and bonded via any suitable process (e.g., wedge bond, stitch bond, etc.).

A mold 124 (e.g., a plastic, a ceramic, etc.) encapsulates the integrated circuit 118 to protect the contents of the example packaged integrated circuit 100 (e.g., bond wires 120, pads 104, etc.) from the environment. The packaged integrated circuit 100 also includes one or more conductive elements 126 disposed on the second surface 112 of the substrate 102 to facilitate electrical and mechanical attachment of the packaged integrated circuit 100 to, for example, a circuit board. In the illustrated example, the conductive elements 126 are disposed over the holes 108 and are in electrical communication with the pads 104. The conductive elements 126 are implemented by any suitable material, for example, a solder.

The example packaged integrated circuit 100 includes one or more surface mount devices 130 (e.g., a resistor, a capacitor, an inductor, a passive filter, a diode, etc.) disposed on the second surface 112 of the substrate 102. Surface mount devices are small (e.g., a surface mount device having a 01005 package size is 400 microns long and 200 microns wide) and can implement virtually any circuit element (e.g., capacitors, inductors, transistors, circuits, etc.). In the illustrated example, the surface mount device 130a is implemented by a two terminal (i.e., two electrical contacts) device. However, the surface mount device 130a can be implemented with any desired number of terminals.

In the illustrated example, the surface mount device 130a is electrically coupled to contacts 122 of the integrated circuit 118 via the plugs 110. Particularly, the surface mount devices 130 are electrically coupled to their respective plugs 110 via one or more second conductive elements 132. The second conductive elements 132 are implemented via any suitable material to electrically couple the surface mount devices 130 to the plugs (e.g., a conductive epoxy, a high temperature solder, a solder, etc.). In the example of FIG. 1, a first terminal 134 of the surface mount device 130a is electrically coupled to the plug 110a and a second terminal 136 of the surface mount device 130a is electrically coupled to the plug 110b. As a result, the pad 104a is electrically coupled to the pad 104b via the surface mount device 130a.

In the example of FIG. 1, the second conductive elements 132 are implemented by a solder, which may reflow during later process (e.g., attachment to a circuit board, etc.). When the second conductive elements 132 reflow, the second conductive elements 132 change their phase from solid to liquid, which may result in uncoupling the surface mount device 130 from their respective plugs 110. To prevent such uncoupling, in some examples, the second conductive elements 132 may be implemented by a different material than the first conductive elements 126. For example, the second conductive elements may be implemented by a high temperature solder that has a melting temperature that is higher than a melting temperature of the first conductive elements 126.

Still, in other examples, to keep the surface mount devices 130 in a substantially fixed location on the second surface 112 of the substrate 102, one or more fastening elements 138 (e.g., an epoxy, etc.) may further fasten the surface mount devices 130 to the substrate 102. In the example of FIG. 1, the second fastening elements 138 selectively encapsulate the surface mount devices 130 to secure the surface mount devices 130 in a fixed position during other processes.

FIG. 2 illustrates the example packaged integrated circuit 100 of FIG. 1 attached to a circuit board 202 of an example electronic device (not shown). The example packaged integrated circuit 100 is attached to one or more pads 204 on the circuit board 202 via the first conductive elements 126. In the example of FIG. 2, the surface mount devices 130 are attached to the bottom surface 112 of the substrate 102 without requiring additional area on the circuit board 202 or on the first surface 106 of the substrate 102.

In some examples, the surface mount devices 130 may be selected to isolate noise from high-density electronic devices (e.g., digital signal processors, computer processors, transceivers, etc.) from other circuitry. As illustrated in the example of FIG. 2, the surface mount devices 130a shunt the corresponding contacts 122 of the integrated circuit to a reference signal (e.g., ground, etc.). In such examples, the surface mount device 130a forms a low impedance path at high frequencies to thereby reduce or eliminate undesired effects due to the high-density of the integrated circuit 118 (e.g., switching noise, electromagnetic interference, etc.).

In such examples, due to the high density of contacts 122 and bond wires 120 in such integrated circuits, the surface mount devices 130 reduces electromagnetic interference effects and improves performance of the overall circuit. However, the surface mount devices 130 may be selected to perform any suitable function. For example, the surface mount device 130a may implement a matching impedance to prevent signal reflection. Still, in other examples, the surface mount devices 130 may be implemented to reduce one or more parasitics associated with the packaged integrated circuit 100 (e.g., effective series inductance, effective series resistance, etc.).

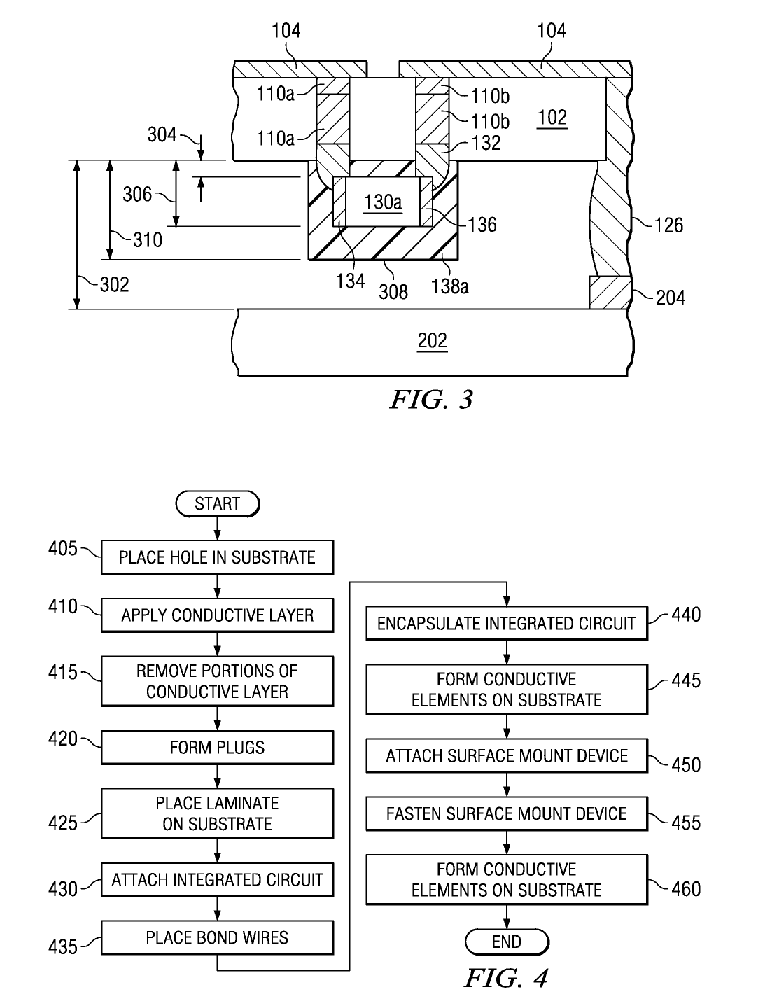

FIG. 3 illustrates the surface mount device 130a of FIG. 2 attached to the second surface 112 of the substrate 102 in yet more detail. In the example of FIG. 3, after the packaged integrated circuit 100 is attached to the circuit board 202 via the conductive elements 126, the packaged integrated circuit 100 and the circuit board 202 are separated by a first distance 302. In some examples, the first distance 302 is approximately 15-25 mils. In the illustrated example, except for its contact terminals, the surface mount device 130a is not in contact with the second surface 112 of the substrate 102. As a result, the sum of a thickness of the surface mount device 130a and a second distance 304 between the surface mount device 130a and the second surface 112 form a third distance 306. Generally, the surface mount device 130a is selected so that the third distance 306 does not exceed the first distance 302.

Still, in other examples, the fastening element 138 further fastens the surface mount device 130a to the second surface 112 of the substrate 102. In the example of FIG. 3, the fastening element 138a encapsulates the surface mount device 130a. As a result, the distance from a first surface 308 of the adhesive 138a to the second surface 112 of the substrate 102 forms a fourth distance 310. In such examples the fastening element 138a is applied such that the fourth distance 310 does not exceed the first distance 302. The fastening element 138a may also be applied so that a thickness of the fastening element 138a does not exceed the third distance 306, thereby partially encapsulating the surface mount device 130a with the fastening element 138a (i.e., one or more surfaces of the surface mount device 130a are exposed to the environment).

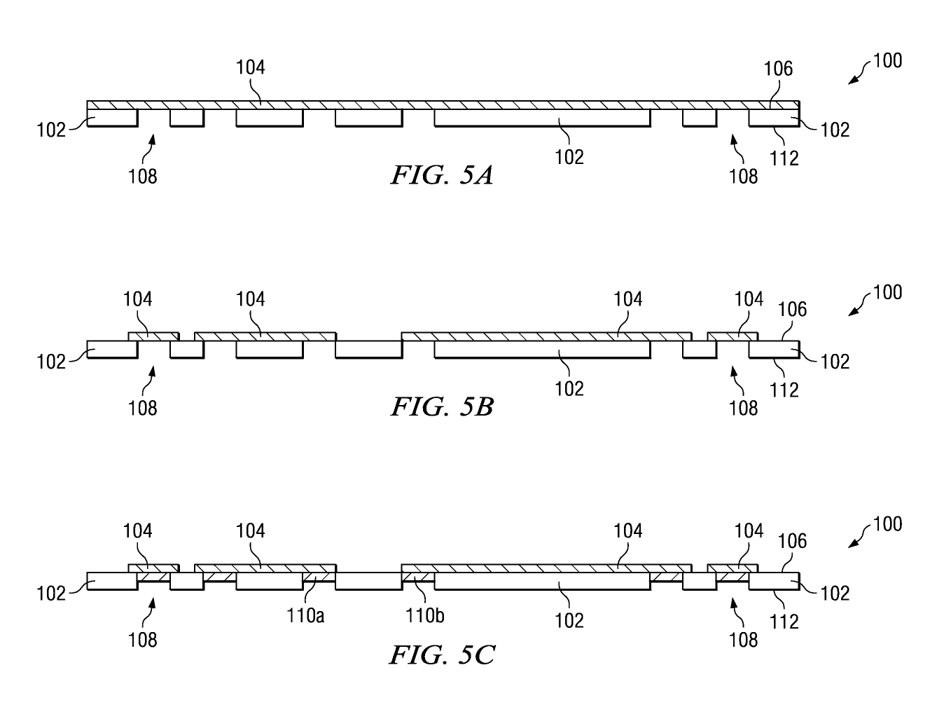

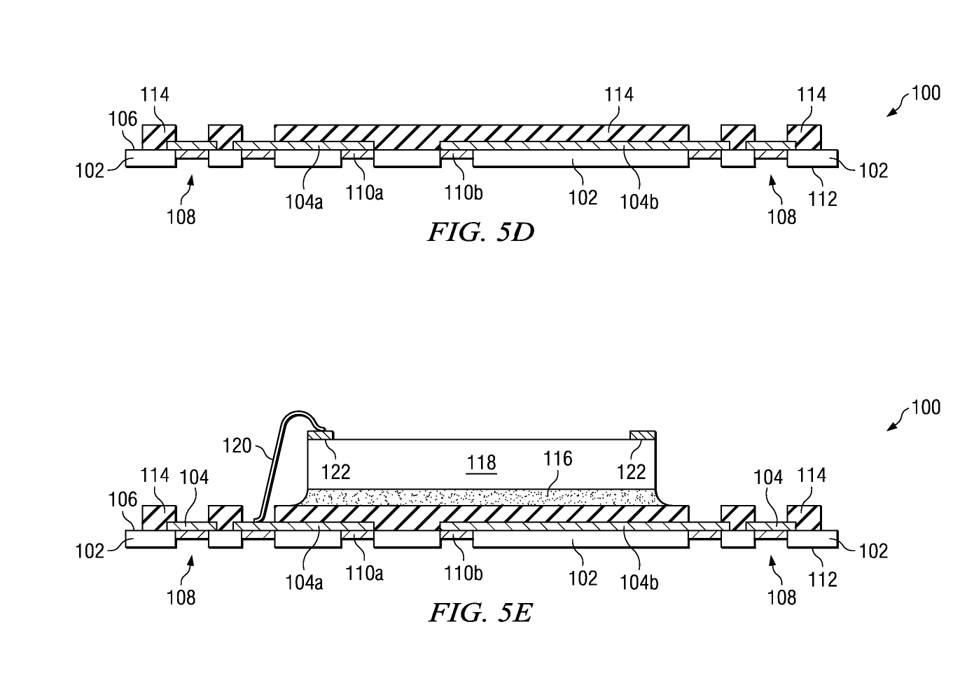

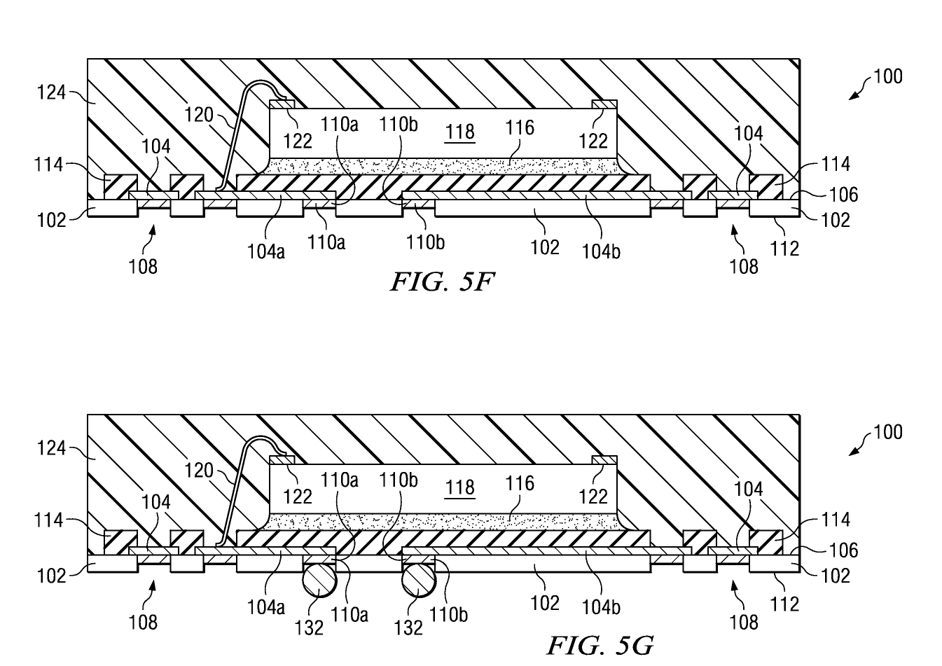

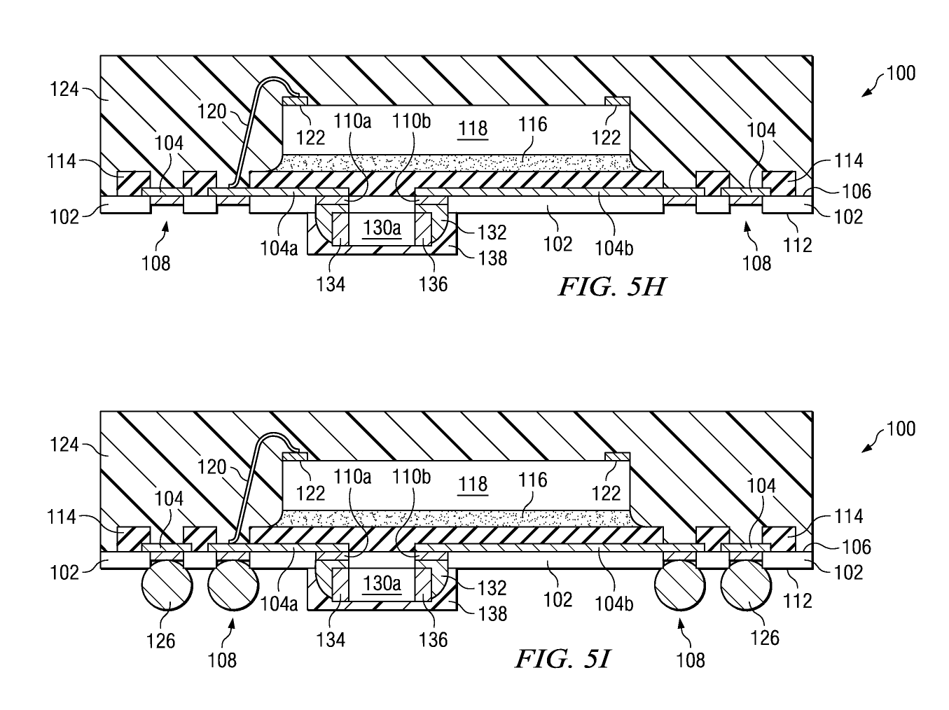

FIG. 4 is a flow chart representing an example process 400 to form the example packaged integrated circuit 100 of FIGS. 1-3. The example process 400 will be explained in conjunction with FIGS. 5A-5I, which illustrate the example packaged integrated circuit 100 at different stages of the example process 400.

Referring to the example of FIG. 5A, the example process 400 begins by forming the holes 108 in the substrate 102 (block 405). In some examples the substrate 102 is implemented by a dielectric (e.g., a polyimide tape, etc.) that is typically thin (e.g., 80 microns). Such an example substrate 102 is inexpensive and is commonly used in high volume manufacturing of semiconductor devices. The holes 108 may be implemented via any suitable process (e.g., chemical milling, etch, drill, punch, etc.) In the illustrated example, a conductive layer 104 is then applied to the first surface 106 of the substrate 102 by any suitable process (e.g., attaching a metal tape, a plating process, etc.) (block 410).

As seen in the example of FIG. 5B, the metal layer 104 is selectively removed to form the conductive pads 104 by any suitable process (e.g., strip, etch, etc.), thereby exposing portions of the substrate 102 on its first surface 106 (block 415). As illustrated in the example of FIG. 5C, the plugs 110 (e.g., a copper plug, etc.) are then placed into the holes 108 via any suitable process (e.g., plating, etc.) (block 420). After forming the plugs 110, the example process 400 continues by selectively coating the first surface 106 of the substrate 102 with the protective layer 114 so that portions of the pads 104 remains exposed (block 425). In the example of FIG. 5D, the protective layer 114 is implemented by any suitable material to protect the top surface 106 of the substrate 102 from damage (e.g., a laminate, etc.).

As illustrated in the example of FIG. 5E, the integrated circuit 118 is then attached to the protective layer 114 via the epoxy layer 116 (e.g., an epoxy die bond) (block 430). In other examples, the integrated circuit 118 may be attached to the pads 104 via any other suitable process (e.g., a flip-chip process, a eutectic die attach, etc.). The bond wires 120 are then placed between the contacts 122 of the integrated circuit 118 and their respective pads 104 (block 435). After attaching the integrated circuit 118 and placing the bond wires 120, the mold 124 is formed over the substrate 102 to encapsulate the integrated circuit 118 and its associated devices (e.g., the bond wires 120, the pads 104, etc.) (block 440). As illustrated in the example of FIG. 5F, the mold 124 may be implemented by, for example, a transfer mold process.

After encapsulating the integrated circuit 118, the second conductive elements 132 are selectively formed in the holes 108 via any suitable process (e.g., screen printing solder balls, etc.) (block 445). As illustrated in the example of FIG. 5G, the second conductive elements 132 are in electrical contact with the pads 104. The surface mount devices 130 are then attached to the second surface 112 of the substrate 102 via the second conductive elements 132 (block 450). In the example of FIG. 5H, the conductive elements 132 reflow and electrically and mechanically couple the terminals 134, 136 of the surface mount devices 130 to their respective plugs 110. In some examples, after attaching the surface mount devices 130, one or more fastening elements 138 are then applied to the second surface 112 of the substrate 102 to further fasten the surface mount devices 130 to avoid loosening during later processes (block 455).

As shown in the example of FIG. 5I, the first conductive elements 126 are formed in the holes 108 via any suitable process (e.g., by screen printing, etc.) (block 460). The first conductive elements 126 contact their respective plugs 110. The first conductive elements 126 are formed to have a larger volume than the second conductive elements 132, thereby allowing the surface mount devices 130 to be placed on the substrate 102. In such examples, and as illustrated in the example of FIG. 3, the first conductive elements 124 are selected such that the surface mount devices 130 or the second conductive elements 132 do not contact the circuit board 202. Alternatively or additionally, the first conductive elements 126 are implemented by a different material than the second conductive elements 142.

The example process 400 of FIG. 4 ends after the first conductive elements 126 are placed on the substrate 102. Although the foregoing describes a particular sequence of operations, the sequence of operations of the example process 400 may vary. For example, the stages of the process may be rearranged, combined, or divided. In some examples, stages, processors or operations may be removed. For example, the integrated circuit 118 may be attached via a flip-chip process, thereby not requiring the bond wires 120.

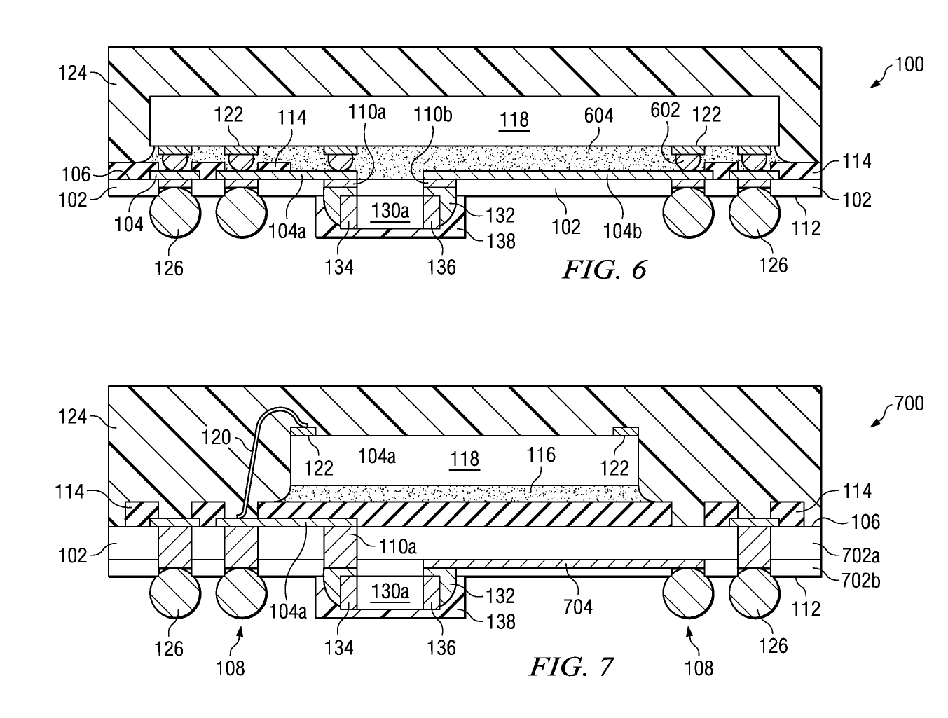

FIG. 6 illustrates an example packaged integrated circuit 600 with the integrated circuit 118 attached to the pads 104 via one or more conductive elements 602. In the example of FIG. 6, the conductive elements 602 are placed on the contacts 122 of the integrated circuit 118, which is flipped over and attached to the pads 104. In the example of FIG. 6, an underfill 604 is applied beneath the integrated circuit 118. The underfill 604 is implemented by any suitable material (e.g., epoxy) and protects the conductive elements 602 (e.g., against stress from thermal expansion, humidity, etc.).

FIG. 7 illustrates another example packaged integrated circuit 700. In the example of FIG. 7, a substrate 102 includes one or more layers 702a-b. As a result, a conductor 704 may be selectively disposed between the layers 702a-b. By implementing a plurality of layers 702, the surface mount devices 130 may be more placed closer in proximity to the contacts 122 and the surface mount devices 130 may be placed more flexibly.

FIG. 8 illustrates another example packaged integrated circuit 800. In the example of FIG. 8, the contact 122a is electrically coupled in contact with the contact 122b via the surface mount device 130a. For example, the surface mount device 130a may implement a direct current (DC) block via placing a capacitor between the contacts 122a-b of the integrated circuit 118. In other examples, the surface mount devices 130 may be placed on the second surface 112 of the substrate 102 for any other suitable function (e.g., filtering, impedance matching, decoupling, etc.). Still, in other examples, any other device (e.g., an active device such a transistor, a diode, etc.) may be placed on the second surface 112 of the substrate 102.

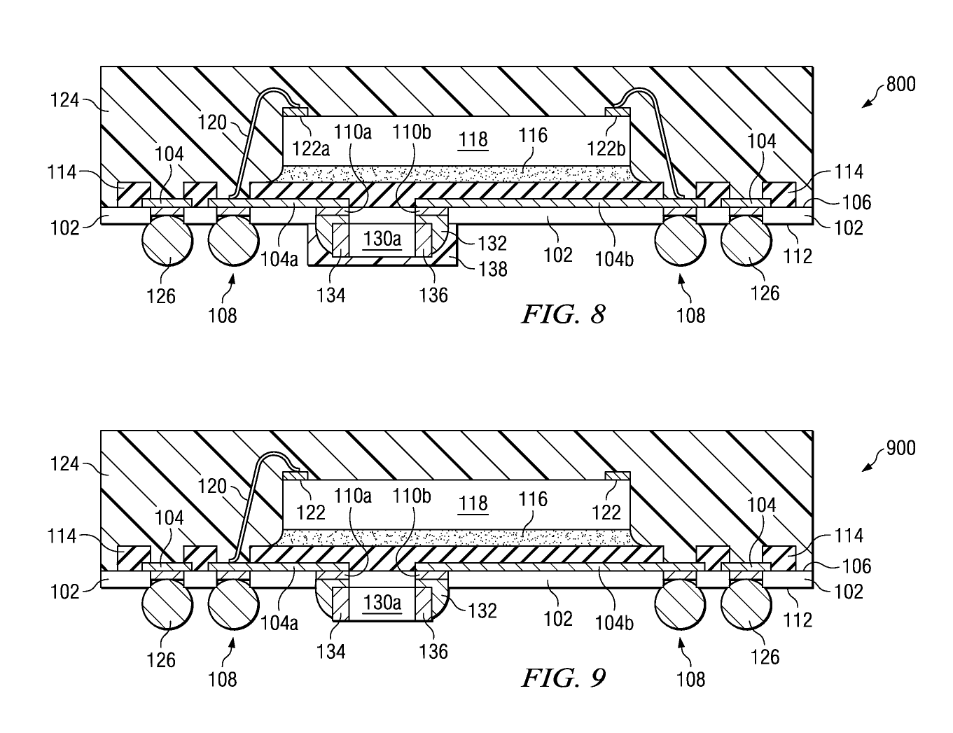

FIG. 9 illustrates yet another example packaged integrated circuit 900. In the example of FIG. 9, the first conductive elements 126 are formed by placing a solder having a first melting temperature (i.e., a temperature at which the solder changes phase from solid to liquid). The second conductive elements 132 are formed by placing a high-temperature solder having a second melting temperature. In the example of FIG. 9, the second melting temperature is larger than the first melting temperature. As a result, the surface mount devices 130 remain in a fixed position during later processes, for example, when the first conductive elements 126 are reflowed to attach the packaged integrated circuit 800 to a circuit board.

In the described examples, surface mount devices are implemented onto the bottom surface of packaged integrated circuits. Prior to this disclosure, there was no cost effective way of mounting surface mount devices in the packages due to the limited area on the substrate. Generally, such surface mount devices cost less than comparable embedded devices that have been placed on the top surface of the package, thereby achieving additional cost savings. In the described examples, the surface mount devices do not consume area on the top surface of the package or on the top of the circuit board, thereby conserving space on both the package and the circuit board and increasing the level of integration. In addition, methods and apparatus to attach and secure the surface mount devices during later processes are also disclosed. In addition, the examples described above are easy to implement using current technology without increasing the manufacturing costs.

Although certain methods, systems, and articles of manufacture have been described herein, the scope of coverage of this patent is not limited thereto. To the contrary, this patent covers all methods, systems, and articles of manufacture fairly falling within the scope of the appended claims either literally or under the doctrine of equivalents.

1. A packaged integrated circuit, comprising:
an integrated circuit mounted on a first surface of a substrate;
a first conductive element mounted on the substrate, the first conductive element being electrically coupled to the integrated circuit;
a second conductive element on a second surface of the substrate opposite the first surface; and
a surface mount device attached to the second surface of the substrate, the surface mount device being electrically coupled to the integrated circuit via the first conductive elements.

2. The apparatus as defined in claim 1, wherein the surface mount device comprises at least one of a capacitor, an inductor, a diode, a transistor, a circuit, or a resistor.

3. The apparatus as defined in claim 1, wherein the surface mount device comprises one or more terminals electrically coupled to the integrated circuit via the first conductive elements.

4. The apparatus as defined in claim 1, wherein the surface mount device extends a first distance relative to the second surface of the substrate and the second conductive elements extends a second distance relative to the second surface of the substrate, the second distance being greater than the first distance.

5. The apparatus as defined in claim 4, further comprising a fastening element to fasten the surface mount device to the second surface of the substrate.

6. The apparatus as defined in claim 5, wherein the fastening element is to at least partially encapsulate the surface mount device to the second surface of the substrate.

7. The apparatus as defined in claim 5, wherein the fastener is to substantially fix the location of the surface mount device during a fabrication process.

8. The apparatus as defined in claim 5, wherein the fastening element extends a third distance relative to the second surface of the substrate, the second distance being greater than the third distance.

9. The apparatus as defined in claim 1, wherein the first conductive element is a first material and the second conductive element is a second material different from the first material.

10. The apparatus as defined in claim 9, wherein the first conductive element has a first melting temperature and the second conductive element has a second melting temperature that is substantially less than the first melting temperature.

11. A method of manufacturing an integrated circuit, comprising:
attaching an integrated circuit to a first side of a substrate;
forming one or more first conductive elements on the substrate;
attaching a surface mount device to a second side of the substrate via the first conductive elements; and
forming one or more second conductive elements on the second side of the substrate.

12. The method as defined in claimed 11, wherein the second conductive elements extend a first distance relative to the second side of the substrate and the surface mount device extends a second distance relative to the second side of the substrate, the second distance being greater than the first distance.

13. The method as defined in claimed 12, further comprising fastening the surface mount device via a fastening element.

14. The method as defined in claim 13, wherein the fastening element extends a third distance relative to the second side of the substrate, the second distance being greater than the third distance.

15. The method as defined in claim 13, wherein fastening the surface mount device to the substrate via the fastening element comprises encapsulating the surface mount device in the fastening element.

16. The method as defined in claim 11, further comprising placing a hole in the substrate through which the first conductive elements are electrically coupled to the integrated circuit.

17. The method as defined in claim 16, further comprising forming a plug in the hole in the substrate, wherein the first conductive elements are electrically coupled to the integrated circuit.

18. The apparatus as defined in claim 1, wherein the surface mount device is electrically coupled to the integrated circuit via a conductive plug.

19. The apparatus as defined in claim 18, wherein the conductive plug is mounted in a hole in the substrate and is electrically coupled to the first conductive element.

20. An electronic device, comprising:
a circuit board; and
a packaged integrated circuit attached to a first side of the circuit board, the packaged integrated circuit comprising:
an integrated circuit adjacent a first surface of a substrate;
a conductive plug mounted in a hole in the substrate;
a first conductive element adjacent a second surface of the substrate opposite the first surface, the first conductive element being electrically coupled to the integrated circuit via the conductive plug;
a second conductive element adjacent the second surface of the substrate, the packaged integrated circuit being attached to the circuit board via the second conductive elements; and
a surface mount device attached to the second surface of the substrate via the first conductive element, the surface mount device being electrically coupled to the integrated circuit via the first conductive element and the conductive plug.
